(19) United States
(12) Patent Application Publication
(10) Pub. No.: US 2006/0156135 A1
(43) Pub. Date: Jul. 13, 2006

(54) Tabbed form with error indicators

(76) Inventor: Marek Sikora, Trinec (CZ)

Correspondence Address: Kris T. Fredrick;Patent Services, Honeywell International Inc., 101 Columbia Road, Morristown, NJ, 07962, US

(21) Appl. No.: 11/016,282

(22) Filed: Dec. 16, 2004

(51) Int. Cl. G06F 11/00; G01R 31/28

(52) U.S. Cl. 714/735

(57) ABSTRACT

An improved graphical user interface having a tab feature. In addition to conventional tabs, each one containing a specific field to be filled, an image is added to all tab captions to indicate if each tab is correctly filled. If the tab is not correctly filled, there is an error indicator with a tool tip identifying what is wrong with the entry. Once the error has been corrected, the indicator changes to show that it is correct.

### FIELD OF THE INVENTION

The present invention relates in general to a document editing system and method using toolbars. More particularly, the present invention relates to the addition of an image to tab captions to indicate if each tab is correctly filled.

### BACKGROUND OF THE INVENTION

When a data system or other information system uses a form with a lot of fields to fill, several tabs are usually employed. Each tab contains a field. At the present time, the user doesn't have the information that is already correctly filled in, such as an address or return address and the like. The user also does not know what is missing because he or she only sees the selected tab.

U.S. Patent Application No. 2002/0116399 to Camps et al. discloses a document editing system and method employing tab features (0074), arrow correction (0039, 0064, 0070), toolbars (0049, 0054). U.S. Patent Application No. 2003/0164859 discloses a user interface having a tabbed form for editing (0008, 0009, 0014), and checks for error conditions and validation (0004).

U.S. Pat. Nos. 5,644,737 and 6,524,831 disclose toolbars generally but make no distinction between correct and incorrect filling of the tabs. U.S. Pat. Nos. 5,999,179, 6,272,537 and 6,664,978 relate to client-server network management that allows a remote user to see data as though the user were present at the network. None of the prior art has recognized the need to distinguish between correct data and missing or incorrect data.

It would be of great advantage if some method could be devised to indicate to a user whether or not a tab is correctly filled.

Another advantage would be if some method could be devised to indicate to a user that the tab is incorrectly filled.

Other advantages and features will appear hereinafter.

### SUMMARY OF THE INVENTION

The present invention provides a data entry system and method having tab forms for entering data therein in a computer by a user using a tab and keyboard. The system and method includes a comparator for comparing each tab form entry with a valid entry and determining the existence of an error entry or a correct entry. The status of the entry is shown by an indicator indicating a sign on the form at a location proximate each form. The sign indicates an error entry or a correct entry based on information from the comparator.

A tool tip is used to provide further information about the error. The tool tip is visible upon request from the user, such as by pointing an arrow on the error indicator. The data entry system is intended to be displayed on a computer screen and the tool tip is activated by contact with a computer arrow on the indicator sign displayed after entry of data in a form.

After an entry has been changed, the comparator re-compares new data entry to again determine the existence of an error entry or a correct entry. The indicator indicates a sign each time a correction is made.

### BRIEF DESCRIPTION OF THE DRAWINGS

For a more complete understanding of the invention, reference is hereby made to the drawings, in which:

FIG. 1 is a pictorial representation of a conventional tab form with data entered in two forms;

FIG. 2 is a pictorial representation of the form of FIG. 1 in which an error is indicated;

FIG. 3 is a pictorial representation of the form of FIGS. 1 and 2 with a tool tip indicating additional information; and

FIG. 4 is a pictorial representation of the tabbed form of this invention after the error has been corrected.

In the figures, like reference characters designate identical or corresponding components and units throughout the several views.

### DETAILED DESCRIPTION OF THE PREFERRED EMBODIMENT

The present invention is applicable to data entry systems where data is entered into a form in a computer by using the tab to move from one entry page to the next. Conventional systems and methods allow multiple pages with various setting to fit one window or entry point. The settings are usually grouped by categories.

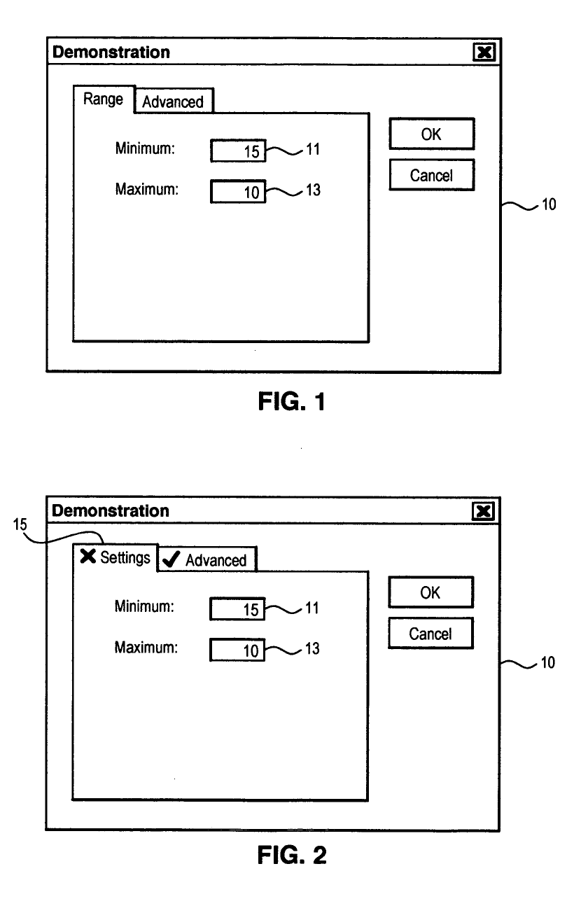

Referring to the figures, FIG. 1 pictorial representation of a typical form 10 in which a user enters data into a series of at least two tab forms 11 and 13. The data entered goes to a comparator, usually a software algorithm in the computer, where it is compared to valid data. For example, valid data may be required to be a positive number, or certain words like “yes” or “no” as can be found on present data entry systems. Valid data may also be required to fall within a specific or predetermined range, such as between the melting point and boiling point of a material such as water. Valid data may also have certain predetermined units of measure, such as currency units, pressure or other scientific values, or other forms of data. The comparator is preferably designed to compare entries in at least two tab forms to determine if the relationship between the tab forms is valid. For example it may be necessary to know if one field is larger than another. The relationship may also be based on the relative numerical value for each entry, so that a whole range of entries may be compared.

Once the comparator has determined the relationship between entered data and valid data, an indicator receives that information and determines if the entered data is an error or correct. If the data is correct, indicator displays a correct symbol. If an error is present, it is indicated on or near the form.

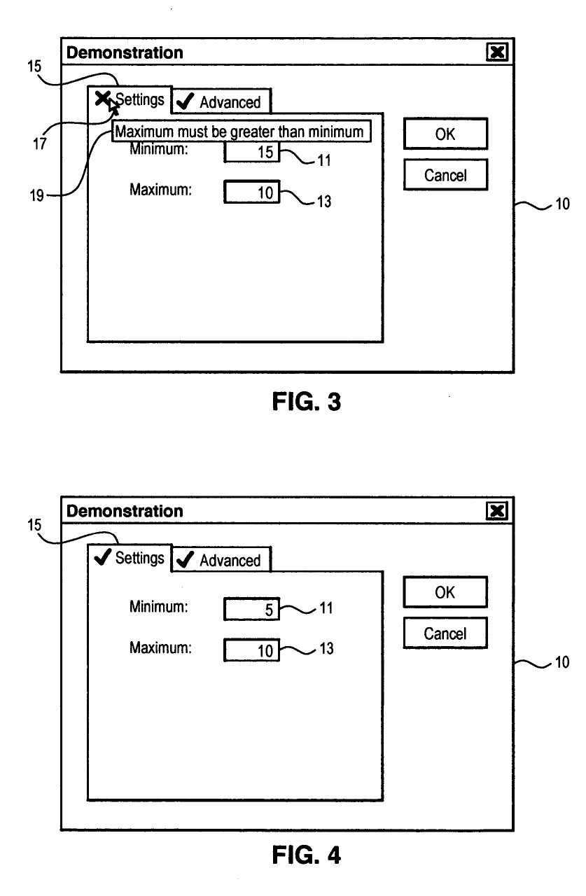

A tool tip is available to display further information about the error. The user then may re-enter data 23 in the field showing an error and the comparison 25 between entered data and valid data In FIG. 2, an x is used, optionally colored red or another color, at 15 so that the user immediately knows if the data she or he has entered is or is not correct. In FIG. 3, the arrow 17 of the computer is pointed on the error sign 15, and a message 19 is displayed, such as “maximum must be greater than minimum.” This functions like the tool tip in Microsoft® Word when one points on a button on the toolbar. In FIG. 4, the correct value has been inserted in filed 11 and the setting 15 indicates a true value, shown as a check mark instead of an x.

While particular embodiments of the present invention have been illustrated and described, they are merely exemplary and a person skilled in the art may make variations and modifications to the embodiments described herein without departing from the spirit and scope of the present invention. All such equivalent variations and modifications are intended to be included within the scope of this invention, and it is not intended to limit the invention, except as defined by the following claims.

1. A data entry system having tab forms for entering data therein in a computer by a user, comprising:
a comparator for comparing each tab form entry with a valid entry and determining the existence of an error entry or a correct entry;
an indicator for indicating a sign on the form at a location proximate each form, said sign indicating an error entry or a correct entry based on information from said comparator;
a tool tip for indicating further information about the error, said tool tip being visible upon request from the user;
whereby said comparator re-compares new data entry to determine the existence of an error entry or a correct entry and said indicator indicates a sign each time a correction is made.

2. The system of claim 1, wherein said valid entry includes a valid range of entries within which the correct entry must fall.

3. The system of claim 1, wherein said valid entry includes valid units of measure for which the correct entry must fall.

4. The system of claim 1, wherein said system is displayed on a computer screen and said tool tip is activated by contact with a computer arrow on the indicator sign displayed after entry of data in a form.

5. The system of claim 1, wherein said comparator compares entries in at least two tab forms to determine if the relationship between said at least two tab forms is valid.

6. The system of claim 5, wherein said relationship is based on the relative numerical value for each entry.

7. A data entry system having tab forms for entering data therein in a computer by a user, comprising:
comparator means for comparing each tab form entry with a valid entry and determining the existence of an error entry or a correct entry;
indicator means for indicating a sign on the form at a location proximate each form, said sign indicating an error entry or a correct entry based on information from said comparator means;
tool tip means for indicating further information about the error, said tool tip means being visible upon request from the user;
whereby said comparator means re-compares new data entry to determine the existence of an error entry or a correct entry and said indicator means indicates a sign each time a correction is made.

8. The system of claim 7, wherein said valid entry includes a valid range of entries within which the correct entry must fall.

9. The system of claim 7, wherein said valid entry includes valid units of measure for which the correct entry must fall.

10. The system of claim 7, wherein said system is displayed on a computer screen and said tool tip is activated by contact with a computer arrow on the indicator sign displayed after entry of data in a form.

11. The system of claim 7, wherein said comparator compares entries in at least two tab forms to determine if the relationship between said at least two tab forms is valid.

12. The system of claim 11, wherein said relationship is based on the relative numerical value for each entry.

13. A method of verifying data entered into a data entry system having tab forms in a computer by a user, comprising:
comparing each tab form entry with a valid entry and determining the existence of an error entry or a correct entry;
indicating a sign on the form at a location proximate each form, said sign indicating an error entry or a correct entry based on information from said comparator means;
indicating further information about the error with a tool tip, said tool tip means being visible upon request from the user; and
re-comparing each new data entry to determine the existence of an error entry or a correct entry and said indicator means indicates a sign each time a correction is made.

14. The method of claim 13, wherein said valid entry includes a valid range of entries within which the correct entry must fall.

15. The method of claim 13, wherein said valid entry includes valid units of measure for which the correct entry must fall.

16. The method of claim 13, wherein said system is displayed on a computer screen and said tool tip is activated by contact with a computer arrow on the indicator sign displayed after entry of data in a form.

17. The method of claim 13, wherein said comparator compares entries in at least two tab forms to determine if the relationship between said at least two tab forms is valid.

18. The method of claim 17, wherein said relationship is based on the relative numerical value for each entry.
